(19) United States
(12) Patent Application Publication
(10) Pub. No.: US 2025/0185320 A1
(43) Pub. Date: Jun. 5, 2025

(54) SEMICONDUCTOR COMPONENT AND METHOD FOR PRODUCING A SEMICONDUCTOR COMPONENT

(71) Applicant: Robert Bosch GmbH, Stuttgart (DE)

(72) Inventors: Alberto Martinez-Limia, Pliezhausen (DE); Dragos Costachescu, Reutlingen (DE); Holger Bartolf, Ofterdingen (DE); Jan-Hendrik Alsmeier, Pfullingen (DE); Stephan Schwaiger, Bodelshausen (DE); Wolfgang Feiler, Reutlingen (DE)

(21) Appl. No.: 18/953,662

(22) Filed: Nov. 20, 2024

(30) Foreign Application Priority Data
Dec. 1, 2023 (DE) 10 2023 212 055.0

(51) Int. Cl. H10D 62/17; H10D 30/66; H10D 62/10; H10D 62/80; H10D 62/832; H10D 62/85

(52) U.S. Cl. CPC H10D 62/314; H10D 30/668; H10D 62/107; H10D 62/8325; H10D 62/8503; H10D 62/875

(57) ABSTRACT

A semiconductor component, in particular a transistor. The semiconductor component includes: a first-type-doped source layer, an second-type-doped channel layer, a first-type-doped drift region, a substrate layer, the channel layer being located between the source layer and the substrate layer and is adjacent to the source layer, wherein the drift region is located between the channel layer and the substrate layer, wherein the semiconductor component includes a gate trench, which extends vertically from the source layer toward the drift region and is adjacent to the channel layer and at least a portion of the source layer; and a second-type-doped shielding region, which extends vertically from the source layer toward the drift region, is adjacent to the channel layer and the source layer and is laterally separated from the gate trench, and wherein the drift region includes a plurality of first-type-doped drift layers, which each have a different doping concentration.

### FIELD

The present invention relates to a semiconductor component, in particular a transistor, e.g., a so-called trench MISFET, and to a method for producing such a semiconductor component.

### BACKGROUND INFORMATION

Semiconductor components such as field-effect transistors (FETs), in particular so-called MOSFETS or MISFETs, are used in various fields. A variant thereof are so-called trench MISFETs or T-MISFETs, in which one channel is vertical. In this case, for example, an n-doped source layer and a channel layer located between this source layer and an n-doped drift layer are interrupted by trenches; gate electrodes are then arranged in such trenches.

### SUMMARY

According to the present invention, a semiconductor component and a method for producing a semiconductor component are provided. Advantageous example embodiments of the present invention are disclosed herein.

The present invention relates to semiconductor components and their production. In particular transistors, preferably field-effect transistors, viz., in particular with trenches, come into consideration as semiconductor components. They may then, for example, be T-MOSFETs or T-MISFETs. Different types of doping, specifically n-doping and p-doping, are used with semiconductor materials, wherein different components can be doped differently.

For the sake of clarity, semiconductor components are to be described below with a specific type of doping; n-doping is to be a doping of a first type, p-doping is to be a doping of a second type. However, it is understood that n-doping and p-doping can also be interchanged; i.e., the n-doping could be the second type of doping and the p-doping could be the first type of doping.

A field-effect transistor has, for example, an n-doped source layer, a generally p-doped channel layer (also body layer), an n-doped drift region and a substrate layer. The channel layer is located between the source layer and the substrate layer and is in particular adjacent to the source layer. The drift region is located between the channel layer and the substrate layer. The field-effect transistor may also have an n-doped spread layer, which is located between the channel layer and the drift region. In addition to the substrate layer, the field-effect transistor also optionally has a buffer layer, which is adjacent to the substrate layer and then also to the drift region.

In addition, a field-effect transistor has, for example, a gate trench, which extends vertically from the source layer toward the drift region and is adjacent to the channel layer and at least a portion of the source layer. In addition, the field-effect transistor in particular has a gate electrode, which is insulated from the spread layer, the source layer and the channel layer and is introduced into the gate trench. For this purpose, a conductive gate electrode material of the gate electrode is at least partially surrounded by a dielectric (e.g., so-called gate oxide), for example. A field-effect transistor may also have a plurality of these gate trenches, wherein such a gate electrode can then be arranged in each gate trench.

In addition, a field-effect transistor typically has a drain contact layer, e.g., a metal, which is used for contacting and is adjacent to the substrate layer. The field-effect transistor may also have a source contact layer, e.g., also a metal, which is used for contacting and is adjacent to the source layer. However, the gate electrode is insulated from the source contact layer by an insulation layer. Therefore, there are source connections and drain connections, which can be formed in the conventional way.

Furthermore, such a field-effect transistor may have at least one p-doped shielding region, which extends vertically from the n-doped source layer, or from a semiconductor surface adjacent to (bordering) said layer (the n-doped source layer), to the n-doped drain layer.

A particular advantage of a trench MISFET is, for example, that the vertical arrangement allows many gate electrodes to be arranged next to one another, in which case a high channel density and low forward resistance can be achieved. The field-effect transistor may in particular be formed as a SiC or GaN field-effect transistor, i.e., the substrate and/or a commonly used semiconductor material may be silicon carbide (SiC) or gallium nitride (GaN) since these semiconductor materials have a wide band gap. However, semiconductor materials having an ultra-wide band gap, for example gallium oxide, can also be considered. However, the present invention can in general also be used with other semiconductor materials, such as gallium nitride (GaN), silicon (Si) or germanium (Ge).

In such field-effect transistors, e.g., silicon carbide (SiC) trench-gate power MISFETs, it is generally desirable to minimize the forward resistance Ron*A (in the on-state of the component and low voltage between drain and source) and to maximize the reverse voltage (in the switched-off state of the component and high voltage between drain and source), while keeping the field load on the gate oxide below acceptable values and maximizing the robustness of the field-effect transistor to short-circuit events. It has not been possible so far to optimize these four different requirements independently of one another.

According to an example embodiment of the present invention, it provided that the drift layer comprises a plurality of n-doped (or generally first-type-doped) drift layers, which each have a different doping concentration. In particular, the drift layer can have four such drift layers.

Conventionally, the mentioned drift region is, for example, a homogeneously doped layer epitaxially applied to the buffer layer or possibly directly to the substrate layer. The provision of a plurality of layers with different doping concentrations and thus also functions makes it possible to minimize the contribution of the drift region to the forward resistance and to maximize the reverse voltage of the field-effect transistor to values that approach the theoretical limits of unipolar components without a superjunction (so-called non-superjunction-unipolar devices).

In one example embodiment of the present invention, the plurality of drift layers comprises a first drift layer, which is located on the side of the substrate layer. If a buffer layer is provided, the first drift layer in particular has a lower doping concentration than the buffer layer. This first drift layer is used to reduce the electric field vertically at high voltage between drain and source; the doping concentration may, for example, be in the range of 5E15-5E16 cm\hat{ }−3 with a thickness of 0.5 μm-10 μm. This layer can be used to generate a high gradient in the electric field in the blocking case.

In one example embodiment of the present invention, the plurality of drift layers comprises a second drift layer, which is adjacent to the first drift layer, wherein the second drift layer has a lower doping concentration than the first drift layer. This second drift layer is an intermediate voltage barrier layer; the doping concentration may, for example, be in the range of 1E15-5E16 cm\hat{ }−3 with a thickness of 0.5 μm-10 μm. In comparison to other layers, this layer can generate an intermediate gradient in the electric field in the blocking case and can help to support the reverse voltage absorption in the blocking state.

In one example embodiment of the present invention, the plurality of drift layers comprises a third drift layer, which is adjacent to the second drift layer, wherein the third drift layer has a lower doping concentration than the first drift layer and the second drift layer. This third drift layer is a main reverse voltage layer; the doping concentration may, for example, be in the range of 1E15-2E16 cm\hat{ }−3 with a thickness of 0.5 μm-10 μm. This layer can be used to generate a small gradient in the electric field in the event of blocking, so that the level of the blocking voltage (integral of the electric field over the drift zone) is maximized at the same maximum field strength.

In one example embodiment of the present invention, the plurality of drift layers comprises a fourth drift layer, which is adjacent to the third drift layer, wherein the fourth drift layer has a higher doping concentration than the second drift layer and the third drift layer. This fourth drift layer may be a spread epitaxial layer; the doping concentration may, for example, be in the range of 1E15-5E16 cm\hat{ }−3 with a thickness of 0.5 μm-10 μm.

In one example embodiment of the present invention, the fourth drift layer has a doping concentration equal to or lower than the first drift layer. Alternatively, the fourth drift layer may have a higher doping concentration than the first drift layer. However, the doping concentration is always higher than for the second and third drift layers. This fourth drift layer can serve to distribute the current in the conducting state and thus to minimize the contribution of the forward resistance near the trench. In one embodiment, this layer can be additionally strengthened with the aid of subsequent ion implantation.

The field-effect transistor may have a p-doped (or generally second-type-doped) shielding region, which extends vertically from the surface or the source layer toward the drift region, is adjacent to the channel layer and the source layer and is laterally separated from the gate trench. In one embodiment, the field-effect transistor furthermore has a further p-doped (or generally a second-type-doped) shielding region, which extends vertically below the gate trench to or into the drift region. The further shielding region is, for example, connected to the shielding region by at least one, in particular deeply implanted, contact region. The further shielding region may in particular be self-aligning.

The provision of a (self-aligning) shielding region (also called “gate screening implant”) under the trench (so-called bottom p-well, BPW) makes it possible to decouple the requirement for the maximum field strength in the gate insulator from the requirements for on-resistance (Ron*A), breakdown voltage, and short-circuit withstand capability. At the same time, a newly created, narrower JFET region between the (new) shielding region and the possibly already existing shielding region (as mentioned above) limits the saturation current density of the field-effect transistor in the event of a short circuit, thereby limiting the power dissipation density and the heating rate of the component as well as possible thermal damage, which gives the field-effect transistor better short-circuit robustness than previously.

The present invention also relates to a method for producing a semiconductor component or field-effect transistor as described above. According to an example embodiment of the present invention, in the method, the substrate layer is provided, and the plurality of n-doped or first-type-doped drift layers are applied to the substrate layer, either directly or indirectly, i.e., in this case to the buffer layer if present. Further active regions can then be formed on the uppermost, i.e., for example, the fourth, of the plurality of drift layers.

A field-effect transistor as described can be used alone or together with others, for example as a power switch. Preferred fields of application are, for example, in an electric drive train of a vehicle, for example in a current transformer (DC/DC converter, inverter), in charging devices for electrically powered vehicles or in solar inverters.

Further advantages and embodiments of the present invention can be found in the description and the figures.

The present invention is shown schematically in the figures on the basis of exemplary embodiments and is described below with reference to the figures.

### BRIEF DESCRIPTION OF THE DRAWINGS

FIG. 1 schematically shows a semiconductor component for explaining the background of the present invention.

FIG. 2 schematically shows a semiconductor component according to an example embodiment of the present invention.

FIG. 3 schematically shows a sequence of a method according to an example embodiment of the present invention.

### DETAILED DESCRIPTION OF EXAMPLE EMBODIMENTS

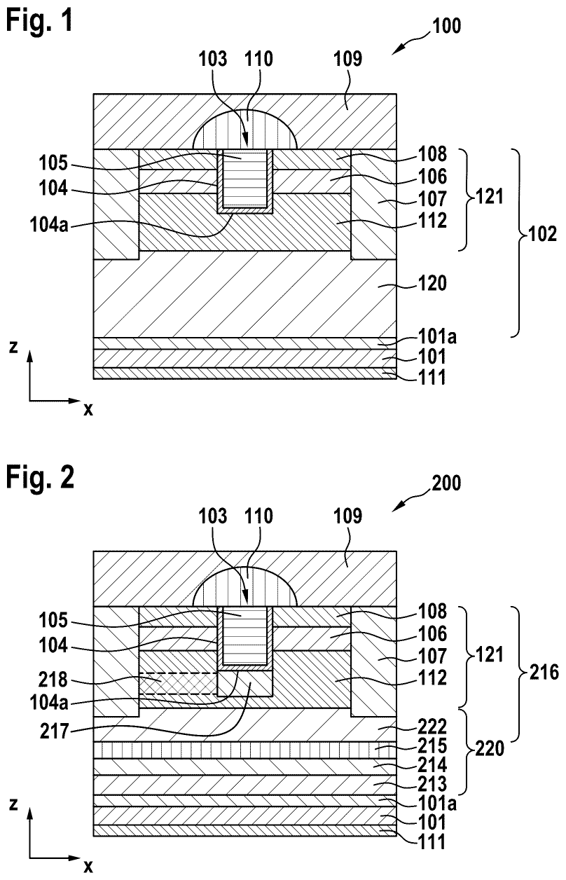

FIG. 1 schematically shows a semiconductor component 100 (or at least a portion thereof) for explaining the background of the present invention, viz., as a field-effect transistor, in particular a so-called trench MISFET. Silicon carbide (SiC), gallium nitride (GaN) or gallium oxide can in particular be used as the semiconductor material since these semiconductor materials have a wide to very wide band gap, which is advantageous for the RonA-breakdown voltage compromise in comparison to materials with a narrow band gap. FIG. 1 shows a sectional view through the field-effect transistor 100, wherein the z direction is a vertical direction; the field-effect transistor 100 has a greater extent in the x-y plane (the y direction is out of the plane of the drawing here).

The field-effect transistor 100 with an n-doping as a doping of the first type and a p-doping as a doping of the second type is described below. As already mentioned, the types of doping may also be interchanged.

The field-effect transistor 100 has a substrate layer 101, for example in the form of a wafer. The substrate layer 101 consists in particular of semiconductor material (e.g., SiC) with an optional, epitaxially grown buffer layer 101a on the top side.

The field-effect transistor 100 also has an epitaxially grown, low-n-doped layer 102 with two main functions. In the upper portion of this layer 102, the so-called MISFET head, here denoted by 121, the active functional regions are produced with suitable doping (e.g., by implantation with suitable masks), while the lower portion of the layer 102, known as the drift region and here denoted by 120, mainly absorbs the high voltage in the blocking case as part of a p/n junction.

The active, in particular implanted, functional regions include the following layers. An n+-doped source layer 108, a p-doped channel layer or body layer 106, possibly a p-doped edge termination (not shown), as well as an optional n-doped spread layer 112, and a p+-doped shielding region 107.

Thus, the layer 102 can initially be produced continuously like the drift region 120, but portions thereof can then be adjusted by processing in order to obtain the aforementioned layers. However, the drift region 120 remains, which is then a homogeneously doped layer.

In addition, a trench MISFET may comprise further structures, e.g., a gate trench 103, a dielectric gate insulating layer 104, 104a on the surface of the trench (gate oxide) (e.g., SiO2 or another insulating material, or a combination of multiple insulating materials); here 104 denotes the side layer, 104a the layer on the trench bottom. The thicknesses of the side gate insulating layer 104 and the gate insulating layer 104a on the bottom of the trench may be different. The gate electrode (e.g., polysilicon or metal gate) is denoted here by 105; an insulation layer 110 is applied to the gate electrode.

A source contact layer of the field-effect transistor 100, e.g., a source metal (e.g., aluminum or copper or a combination of different materials) is denoted by 109; this source contact layer 109 is used to contact the source layer 108 and the shielding region 107.

A drain contact layer of the field-effect transistor 100, e.g., a drain metal that contacts the backside of the substrate layer 101, is denoted by 111.

A challenge with silicon carbide (SiC) trench power MISFETs or comparable field-effect transistors is to achieve good conductive properties in the on-state (low area-specific forward resistance Ron*A) together with good short-circuit withstand capability and high reverse voltage and, for reliability reasons, to limit the maximum field strength in the gate insulator of the trench to acceptable values in the order of 3 MV/cm. These four different requirements cannot be optimized independently of one another so that a compromise results between them.

FIG. 2 schematically shows a semiconductor component 200 (or at least a portion thereof) in an embodiment, viz., as a field-effect transistor, in particular a so-called trench MISFET. Silicon carbide (SiC), gallium nitride (GaN) or gallium oxide can in particular be used as the semiconductor material since these semiconductor materials have a wide to very wide band gap. FIG. 2 shows a sectional view through the field-effect transistor 200, wherein the z direction is a vertical direction; the field-effect transistor 200 has a greater extent in the x-y plane (the y direction is out of the plane of the drawing here).

In particular, the differences between the field-effect transistor 200 and the field-effect transistor 100 according to FIG. 1 are explained below. Identical elements, layers or regions are denoted by the same reference signs; different or additional elements, layers or regions are denoted by different reference signs.

The field-effect transistor 100 has a substrate layer 101, for example in the form of a wafer. The substrate layer 101 has a low specific resistance and can be doped with a very high n++ concentration. An optional buffer layer 101a with a specific n+ doping concentration is epitaxially grown on the top side of the substrate layer. This buffer layer is grown to control and reduce crystal defects.

In one embodiment, four drift layers with different doping concentrations and functions are grown on the buffer layer 101a.

The first drift layer 213 is used as a layer for reducing the electric field vertically at high voltage between drain and source and has a lower doping concentration than the buffer layer (e.g., in the range 5E15-5E16 cm\hat{ }−3 with a thickness of 0.5 μm-10 μm). This layer is used to generate a high gradient in the electric field in the blocking case.

The second drift layer 214 is used as an intermediate voltage barrier layer and has a lower doping concentration than the first drift layer (e.g., in the range of 1E15-5E16 cm\hat{ }−3 with a thickness of 0.5 μm-10 μm). In comparison to the layers 213 and 215, this drift layer 214 generates an intermediate gradient in the electric field in the blocking case and helps to support the reverse voltage absorption in the blocking state.

The third drift layer 215 is used as a main reverse voltage layer and has a lower doping concentration than the first drift layer and also a lower doping concentration than the second drift layer (e.g., in the range of 1E15-2E16 cm\hat{ }−3 with a thickness of 0.5 μm-10 μm). This layer is used to generate a small gradient in the electric field in the blocking case, so that the level of the reverse voltage (integral of the electric field over the drift zone) is maximized at the same maximum field strength.

The fourth drift layer 222 is, for example, a spread epitaxial layer and has a higher doping concentration than the second and third drift layers (e.g., in the range of 1E15-5E16 cm\hat{ }−3 with a thickness of 0.5 μm-10 μm). In one variant, it is doped more than the first layer and, in a second variant, it is doped less than or equally to the first layer (but always more highly than the second and third layers). This layer is used to distribute the current in the conducting state and thus to minimize the contribution of the forward resistance near the trench.

In order to obtain the fourth drift layer 222, the layer 216 can be produced as a spread epitaxial layer, comparable to the layer 102 in FIG. 1. In the upper region of the layer 216, the active functional regions are produced with suitable doping and structure. The, for example implanted, active functional regions include the n+-doped source layer 108, a p-doped channel layer or body layer 106, possibly a p-doped edge termination (not shown), as well as an optional n-doped spread layer 112, and a p+-doped shielding region 107.

Optionally, this layer 216 may be additionally strengthened, for example with the aid of a subsequent ion implantation, i.e., an additional spread layer 112 can be formed. This doping does not necessarily have to cover the entire layer 216 and may also have a location-dependent concentration.

A portion of the layer 216 thus remains, namely the fourth drift layer 222, as it is produced, comparable to the drift layer 120 according to FIG. 1. However, instead of the homogeneous drift region 120, there is now a drift region 220 that comprises four drift layers 213, 214, 215, 222 with different doping concentrations.

In addition, in one embodiment, a further p+-doped shielding region 217 is added here, which extends vertically downward below the gate trench, in the case shown into the spread layer 112, generally toward the drift region 220. The shielding region 217 may be directly adjacent to the gate trench but also vertically spaced from it. A p+-doped contact region 218 extends, in particular in a horizontal direction, from this shielding region 217 to a shielding region 107.

This contact region 218 is shown hatched since it may optionally be homogeneous in the y direction, i.e., the region 218 can be present in every x-z section at every point y through the cell in the active region of the component outside the ends of the cell. Alternatively, however, it may also be interrupted in some portions in the y direction, and each of its segments may have a limited extent in the y direction, so that only the region 112 is present where the region 218 is missing. In both cases described, it is also possible for the contact region 218 to be arranged in the right half-cell. If it has interruptions in the y direction, there may also be portions of the contact region 218 that are arranged in the right half-cell and other portions that are arranged in the left half-cell, in particular alternately.

In addition, a trench MISFET may comprise further structures, e.g., the gate trench 103, the dielectric gate insulating layer 104, 104a on the surface of the trench (gate oxide) (e.g., SiO2 or another insulating material); here, 104 denotes the side layer, 104a the layer on the trench bottom. The gate electrode (e.g., polysilicon or metal gate) is denoted here by 105; an insulation layer 110 is applied to the gate electrode.

A source contact layer of the field-effect transistor 200, e.g., a source metal (e.g., aluminum or copper or a combination of different materials) is denoted by 109; this source contact layer 109 is used to contact the source layer 108 and the shielding region 107.

A drain contact layer of the field-effect transistor 200, e.g., a drain metal that contacts the backside of the substrate layer 101, is denoted by 111.

The surface of the gate trench 103 is covered with the gate insulation layer 104, 104a of defined thickness, wherein the gate insulator on the trench bottom, layer 104a, can have a different, e.g., greater, thickness than on the side walls, layer 104. The insulator may, for example, be a homogeneous insulator or an inhomogeneous insulator stack consisting of different layers, for example. Generally, materials such as SiO2, high-k materials, SiN, Al2O3, HfO can be used. In addition, the gate insulator on the trench bottom can consist of a different material than that at the side walls and/or, in the case of an insulator stack, can have a different ratio of insulator materials. The gate electrode 105 is located within the trench 103 and is adjacent to the layers 104, 104a. The gate electrode is separated from the source contact layer 109 by the insulation layer 110 (e.g., intermetallic dielectric).

The shielding region 217 (also referred to as BPW), which is located below the trench bottom, may touch the trench bottom vertically but does not have to. In principle, the shielding region 217 shields the gate insulator 104, 104a from high electric fields that occur at high drain-source voltages, in particular in the trench bottom region, 104a. The p+ shielding regions 107 can therefore be made flatter (i.e., not extend as deeply vertically), making processing less complex, reducing costs, and minimizing damage to the crystals due to the lower implantation energies used for their production.

On the other hand, flatter p+ shielding regions 107 make narrower cell spacing possible since the implantation mask can be defined to be thinner and can be structured more finely, making narrower critical dimensions possible. Flatter p+ shielding regions 107 also lead to a better current distribution in a lateral direction and thus to a lower on-resistance Ron*A. In addition, the dynamic behavior of the intrinsic body diode of the MISFET, for example during reverse recovery (RR), is improved by a lower charge carrier flooding of the drift region during forward operation of the diode (lower total RR charge, lower snappiness of the intrinsic body diode). Robustness to bipolar degradation is also improved. In addition, the relaxation of the electric field in the gate-insulator region by the shielding regions 217 reduces short-channel effects such as drain-induced barrier lowering (DIBL) and in principle makes a design with a flatter body area and a shorter channel possible, which reduces Ron*A.

The shielding region 217 or a plurality thereof is preferably produced by a self-aligning ion implantation in the bottom of the gate trench 103. In this way, the self-alignment of both structures, i.e., gate trench and shielding region 217, is achieved, and the best results in shielding the gate insulator, 104, 104a, from high electric fields without adverse effects on Ron*A are achieved.

Before implantation, a special masking layer may, for example, be grown or deposited on the inner wall of the trench walls in order to protect the n-regions that are laterally adjacent to the trench walls from compensation by the implantation of p-dopants.

The shielding region 217 may alternatively also be produced with p+ shielding regions 107 in one step, wherein doping is carried out through and into the source layer 108 and body layers or channel layers 106 (in the region in which the trench will be located), and the trench is subsequently etched. This production method allows processing costs to be saved by sacrificing a small amount of performance.

The p+ shielding regions 107 do not have to be deeper than the shielding regions 217 and/or the spread layer 112. The spread layer 112 does not have to be deeper than the shielding regions 217.

The shielding regions 217 are connected to the p+ shielding regions 107 and thus to the source potential by deeply implanted contact regions 218, which may be periodically implanted in the third dimension perpendicular to the main longitudinal axis of the trench (in the y direction not shown here).

The contact regions 218 may be implanted at regular intervals, preferably on alternating trench sides (shown only on the left in FIG. 2) but may also be located on both trench sides at the same location in the third dimension. Alternatively, the contact regions 218 may also be arranged on only one side of the trench. The distance from the contact region 218 to the next contact region 218 on the same side of the p+ shielding region 107 can be freely selected. A favorable compromise between low resistance of the component and good connection of the shielding region 217 to the source potential is, for example, approximately 2 to 20 times the cell spacing of the MISFETs. By connecting the shielding region 217 to the source potential, the shielding region 217 is given the functionality to reduce the saturation current of the source-drain current path in the event of a short circuit. Thus, the shielding region 217 increases the short-circuit withstand capability of the field-effect transistor.

The highly doped buffer layer 101a (in comparison to 102, 213, 214, 215, 216 or 222) is optional and can be used to minimize the on-resistance Ron*A through a punch-through design (a high doping level for 101a that, during the blocking state of the component, stops the depletion zone before it reaches the substrate) and to achieve the robustness of the MISFET to bipolar degradation (the high doping level of 101a is accompanied by a short lifetime for the minority carriers, which helps to reduce the plasma concentration in the buffer layer).

Optionally, an additional doping layer may be inserted between the buffer layer 101a and the first drift layer 213 (RR optimization layer, not shown). The doping and thickness of this layer may be optimized to achieve better reverse recovery of the intrinsic body diode, which may be required in some applications.

The spread layer 112 is, as mentioned, also optional. In order to achieve a low forward resistance, said spread layer is more highly doped than the drift region 120 or 220 and may extend vertically from the channel layer or body layer 106 to below the p+ shielding regions 107. The spread layer 112 may have a non-constant doping in a vertical and/or lateral direction and may be produced by multiple ion implantations with different doses and energies. In particular, the doping profile of the spread layer 112 may be retrograde, i.e., the doping concentration reaches a maximum at a certain depth, going vertically downward from the surface.

As mentioned, the proposed designs are not limited to the described n-channel MISFET but may also be applied to a p-channel MISFET by replacing n-dopings with p-dopings and vice versa. In addition, the proposed designs are not limited to SiC but may also be applied to other materials with a wide band gap such as GaN or materials without a wide band gap such as Si.

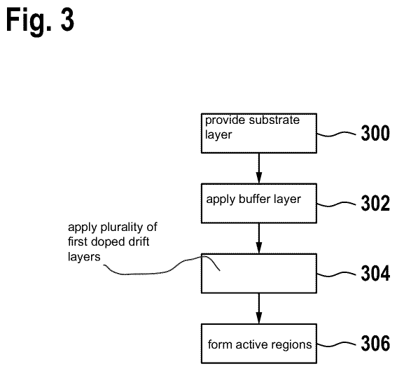

FIG. 3 schematically shows a sequence of a method in a preferred embodiment, viz., by way of example, for producing a field-effect transistor as shown, for example, in FIG. 2. In principle, the production has already been thoroughly described with reference to FIG. 2 but is briefly summarized again below.

In a step 300, the substrate layer can first be provided, whereupon, in the optional step 302, the buffer layer is applied. A plurality of first-type-doped drift layers, including a wide fourth layer, can in turn be applied thereto, step 304. The aforementioned layers, source layer, channel layer, implants for strengthening the spread layer, etc. can then be introduced there, resulting in a final fourth layer. Later in the process, step 306, (further) active regions can then be formed on an uppermost of the plurality of drift layers. Such active regions comprise, for example, the aforementioned shielding regions, channel layer, source layer and the like.

1-10. (canceled)

11. A semiconductor component including transistor, the semiconductor component comprising:
a first-type-doped source layer;
a second-type-doped channel layer;
a first-type-doped drift region;
a substrate layer, wherein the channel layer is located between the source layer and the substrate layer and is adjacent to the source layer, and the drift region is located between the channel layer and the substrate layer;
a gate trench, which extends vertically from the source layer toward the drift region and is adjacent to the channel layer and at least a portion of the source layer; and
a second-type-doped shielding region which extends vertically from the source layer toward the drift region, is adjacent to the channel layer and the source layer, and is laterally separated from the gate trench;
wherein the drift region includes a plurality of first-type-doped drift layers, which each have a different doping concentration.

12. The semiconductor component according to claim 11, wherein the plurality of drift layers include:
a first drift layer, which is located on a side of the substrate layer;
a second drift layer, which is adjacent to the first drift layer, wherein the second drift layer has a lower doping concentration than the first drift layer;
a third drift layer, which is adjacent to the second drift layer, wherein the third drift layer has a lower doping concentration than the first drift layer and the second drift layer; and
a fourth drift layer, which is adjacent to the third drift layer, wherein the fourth drift layer has a higher doping concentration than the second drift layer and the third drift layer.

13. The semiconductor component according to claim 12, wherein:
(i) the fourth drift layer has a doping concentration equal to or lower than the first drift layer, or
(ii) the fourth drift layer has a higher doping concentration than the first drift layer.

14. The semiconductor component according to claim 12, further comprising:
a first-type-doped buffer layer, which is arranged on the substrate layer and is located between the first drift layer and the substrate layer;
wherein the first drift layer has a lower doping concentration than the buffer layer.

15. The semiconductor component according to claim 11, further comprising:
a further second-type-doped shielding region, which extends vertically below the gate trench to or into the drift region, wherein the further shielding region is connected to the shielding region by at least one deeply implanted contact region.

16. The semiconductor component according to claim 15, wherein the shielding region is self-aligning.

17. The semiconductor component according to claim 11, further comprising:
a first-type-doped spread layer, which is located between the channel layer and the drift region.

18. The semiconductor component according to claim 11, further comprising:
a gate electrode, which is insulated from the spread layer and the channel layer and is introduced into the gate trench.

19. The semiconductor component according to claim 11, wherein the semiconductor component is a SiC field-effect transistor or a GaN field-effect transistor or a gallium-oxide field-effect transistor.

20. A method for producing a semiconductor component, the semiconductor component including:
a first-type-doped source layer;
a second-type-doped channel layer;
a first-type-doped drift region;
a substrate layer, wherein the channel layer is located between the source layer and the substrate layer and is adjacent to the source layer, and the drift region is located between the channel layer and the substrate layer;
a gate trench, which extends vertically from the source layer toward the drift region and is adjacent to the channel layer and at least a portion of the source layer; and
a second-type-doped shielding region which extends vertically from the source layer toward the drift region, is adjacent to the channel layer and the source layer, and is laterally separated from the gate trench;
wherein the drift region includes a plurality of first-type-doped drift layers, which each have a different doping concentration,
the method comprising the following steps:
providing the substrate layer;
applying the plurality of first-type-doped drift layers, directly or indirectly, to the substrate layer; and
forming further active regions on an uppermost of the plurality of drift layers.
